(19) United States
(12) Patent Application Publication
(10) Pub. No.: US 2026/0047133 A1
(43) Pub. Date: Feb. 12, 2026

(54) STACKED FET WITH METALLIC SOURCE/DRAIN CONTACT

(71) Applicant: INTERNATIONAL BUSINESS MACHINES CORPORATION, Armonk, NY (US)

(72) Inventors: Utkarsh Bajpai, Suffern, NY (US); Debarghya Sarkar, Latham, NY (US); Ching-Tzu Chen, Ossining, NY (US); Henry K. Utomo, Ridgefield, CT (US)

(21) Appl. No.: 18/798,067

(22) Filed: Aug. 8, 2024

(51) Int. Cl. H01L 29/417; H01L 21/822; H01L 21/8234; H01L 27/06; H01L 27/088; H01L 29/06; H01L 29/423; H01L 29/49; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 64/665; H10D 84/0128; H10D 84/013; H10D 84/0151; H10D 84/038; H10D 84/83; H10D 88/00; H10D 88/01

(57) ABSTRACT

A semiconductor device includes a first field effect transistor stacked on a second field effect transistor. The first field effect transistor has a metallic source/drain region. A second source/drain region of the second field effect transistor is separated from the metallic source/drain region by a middle dielectric isolation layer. A through contact passes through the middle dielectric isolation layer to connect the metallic source/drain region to the second source/drain region.

### BACKGROUND

The present invention generally relates to semiconductor devices and processing methods, and more particularly to stacked field effect transistors (FETs) with metallic source/drain regions.

Stacked transistor devices may be used to increase areal density of devices on a chip. Additionally, the close proximity of the overlying and underlying devices can be useful when forming paired devices, such as complementary semiconductor devices that include two devices of opposing polarity. However, positioning transistors above one another places spatial and electrical constraints that make it challenging to provide required performance and routing connectivity.

Vertical interconnects between layers consume real estate, and high-density devices incur difficulties in wire routing. As cell heights for device cells in stacked structures shrink, electrical wiring must also shrink. This creates resistance bottlenecks as contacts cannot further scale without a performance penalty.

Therefore, devices and methods for fabricating devices are needed to permit further scaling in stacked FETs.

### SUMMARY

In accordance with an embodiment of the present invention, a semiconductor device includes a first field effect transistor stacked on a second field effect transistor. The first field effect transistor has a metallic source/drain region. A second source/drain region of the second field effect transistor is separated from the metallic source/drain region by a middle dielectric isolation layer. A through contact passes through the middle dielectric isolation layer to connect the metallic source/drain region to the second source/drain region.

In other embodiments, the metallic source/drain region can include W or an alloy thereof. The metallic source/drain region can include Co or an alloy thereof. The metallic source/drain region can connect to device channels by channel caps. The second source/drain region can include a metal. The metallic source/drain region can be laterally offset from the second source/drain region. A contact can connect the metallic source/drain region to a back end of the line layer on a frontside of the semiconductor device. A contact can be connected to the second field effect transistor from a backside of the semiconductor device.

In accordance with another embodiment of the present invention, a semiconductor device includes a first field effect transistor stacked on a second field effect transistor, the first field effect transistor having a first metallic source/drain region. A second metallic source/drain region of the second field effect transistor is separated from the first metallic source/drain region by a middle dielectric isolation layer. A through contact passes through the middle dielectric isolation layer to connect the first metallic source/drain region to the second metallic source/drain region.

In other embodiments, the first metallic source/drain region can include W or alloy thereof. The first metallic source/drain region can include Co or alloy thereof. The second metallic source/drain region can include W or alloy thereof. The second metallic source/drain region can include Co or alloy thereof. The first metallic source/drain region can connect to device channels by channel caps. The second metallic source/drain region can connect to device channels by channel caps. The first metallic source/drain region can be laterally offset from the second metallic source/drain region. A contact can be connected to the second field effect transistor from a backside of the semiconductor device.

In accordance with another embodiment of the present invention, a semiconductor device includes a first field effect transistor stacked on a second field effect transistor, the first field effect transistor having a first metallic source/drain region, the first metallic source/drain connecting to device channels of the first field effect transistor by channel caps. A second metallic source/drain region of the second field effect transistor is separated from the first metallic source/drain region by a middle dielectric isolation layer, the second metallic source/drain connecting to device channels of the second field effect transistor by channel caps. A through contact passes through the middle dielectric isolation layer to connect the first metallic source/drain region to the second metallic source/drain region.

In other embodiments, the first metallic source/drain region can be laterally offset from the second metallic source/drain region. A contact can connect the first metallic source/drain region to a back end of the line layer on a frontside of the semiconductor device. A contact can be connected to the second field effect transistor from a backside of the semiconductor device.

In accordance with another embodiment of the present invention, a semiconductor device includes a first field effect transistor stacked on a second field effect transistor, the first field effect transistor having a first metallic source/drain region, the first metallic source/drain connecting to device channels of the first field effect transistor by channel caps. A second metallic source/drain region of the second field effect transistor is separated from the first metallic source/drain region by a middle dielectric isolation layer, the second metallic source/drain connecting to device channels of the second field effect transistor by channel caps. A through contact passes through the middle dielectric isolation layer to connect the first metallic source/drain region to the second metallic source/drain region. A frontside contact connects the first metallic source/drain region to a back end of the line layer. A backside contact is connected to the second field effect transistor from a backside of the semiconductor device to provide power.

In other embodiments, the first metallic source/drain region can be laterally offset from the second metallic source/drain region.

In accordance with another embodiment of the present invention, a method for forming a semiconductor device includes forming a bottom field effect transistor; depositing a middle dielectric isolation layer over the bottom field effect transistor; forming an opening in the middle dielectric isolation layer over a source/drain region of the bottom field effect transistor; forming a placeholder in the opening of the middle dielectric isolation layer; forming channels and gate structures of a top field effect transistor; performing a dielectric fill; opening the dielectric fill over the placeholder; removing the placeholder; and depositing a metal through the middle dielectric isolation layer to form a through contact to the source/drain region of the bottom field effect transistor and to form a metallic source/drain region for the top field effect transistor.

In other embodiments, the metallic source/drain region connects to the channels by the channel caps.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows cross-sectional views, taken at section lines X-cut and Y-cut as shown in an inset, showing gates and source and drain regions formed for a first level of a semiconductor device, in accordance with an embodiment of the present invention;

FIG. 2 shows cross-sectional views, taken at section lines X-cut and Y-cut, showing a middle dielectric isolation layer opened to expose an underlying source/drain region, in accordance with an embodiment of the present invention;

FIG. 3 shows cross-sectional views, taken at section lines X-cut and Y-cut, showing a placeholder formed in the middle dielectric isolation layer, in accordance with an embodiment of the present invention;

FIG. 4 shows cross-sectional views, taken at section lines X-cut and Y-cut, after layers of semiconductor materials for a second level device are bonded to the middle dielectric isolation layer, in accordance with an embodiment of the present invention;

FIG. 5 shows cross-sectional views, taken at section lines X-cut and Y-cut, after the layers of semiconductor materials are patterned, in accordance with an embodiment of the present invention;

FIG. 6 shows cross-sectional views, taken at section lines X-cut and Y-cut, after channel caps are epitaxially grown on channels, in accordance with an embodiment of the present invention;

FIG. 7 shows cross-sectional views, taken at section lines X-cut and Y-cut, after a dielectric fill is formed, in accordance with an embodiment of the present invention;

FIG. 8 shows cross-sectional views, taken at section lines X-cut and Y-cut, after a top gate is formed by a replacement metal gate process, in accordance with an embodiment of the present invention;

FIG. 9 shows cross-sectional views, taken at section lines X-cut and Y-cut, after the dielectric fill is patterned, the placeholder removed and the source/drain region of a bottom field effect transistor is exposed, in accordance with an embodiment of the present invention;

FIG. 10 shows cross-sectional views, taken at section lines X-cut and Y-cut, after a conductive fill forms a through contact in a location of the placeholder and forms a metallic source/drain region for a top field effect transistor, in accordance with an embodiment of the present invention;

FIG. 11 shows cross-sectional views, taken at section lines X-cut and Y-cut, after the conductive fill is recessed, in accordance with an embodiment of the present invention;

FIG. 12 shows cross-sectional views, taken at section lines X-cut and Y-cut, after a dielectric material refills areas where the conductive fill was recessed, in accordance with an embodiment of the present invention;

FIG. 13 shows cross-sectional views, taken at section lines X-cut and Y-cut, after middle of the line frontside contacts are formed, in accordance with an embodiment of the present invention;

FIG. 14 shows cross-sectional views, taken at section lines X-cut and Y-cut, after vias and metal lines for a back end of the line layer are formed on the frontside, in accordance with an embodiment of the present invention;

FIG. 15 shows cross-sectional views, taken at section lines X-cut and Y-cut, after a carrier wafer is applied and the structure is flipped to process a backside and showing a substrate removed, a backside dielectric layer deposited and a backside contact formed, in accordance with an embodiment of the present invention;

FIG. 16 shows cross-sectional views, taken at section lines X-cut and Y-cut, showing a metallic bottom source/drain region connected to the metallic source/drain region of the top field effect transistor by the through contact, in accordance with an embodiment of the present invention; and

FIG. 17 shows cross-sectional views, taken at section lines X-cut and Y-cut, showing a bottom source/drain region offset from the metallic source/drain region of the top field effect transistor, in accordance with an embodiment of the present invention.

### DETAILED DESCRIPTION

In accordance with embodiments of the present invention, devices and methods are described which include dual-function transistor electrodes (source/drain regions) that can function as a source/drain region as well as a signal line. The dual-function transistor electrode includes conductive materials (e.g., metals). The dual-function transistor electrode permits the elimination of a contact connection between stacked layers. A contact connection can pass alongside the source/drain regions. With decreasing cell height, the contact connection would need to shrink. However, by employing a dual-function transistor electrode, the source/drain region and the contact could both employ a larger portion of the cell height. This permits further scaling and eliminates any resistance penalty otherwise caused by reduction in contact connection size.

In an embodiment, a semiconductor device includes a first transistor stacked on a second transistor. The first transistor includes a source/drain region having metallic material (e.g., a metallic source/drain region) and the second transistor includes a source/drain region having an epitaxially grown semiconductor. The metallic material can include a metal or a metal alloy having a conductivity comparable to a metal contact. In an illustrative embodiment, the metallic source/drain region can include a width of, e.g., 20 nm and a cell height of 60-65 nm.

In another embodiment, the second transistor can also include a source/drain region having a metallic material. The first transistor can include a signal-side canyon (that does connect to a power line) that directly connects to the second transistor at a second transistor signal-side canyon by a metallic via directly between the first transistor signal-side canyon and the second transistor signal-side canyon. The metallic via connection can be disposed through a middle dielectric isolation (MDI) layer. The metallic via can be formed integrally with the metallic source/drain region of the first transistor.

In other embodiments, the first and second devices can include channel caps, which include “small” epitaxially grown semiconductor material shapes that directly connect a device channel to metallic material or doped semiconductor in the source/drain regions. Embodiments of the present invention can include transistor devices that can be n-type or p-type. The transistors can be nanosheet transistors, wherein the channel materials can include semiconductor material, such as, e.g., Si, Ge, SiGe, or other semiconductor materials useful for device channels. In other embodiments, quasi-2D van der Waal semiconductor materials including, e.g., transition-metal dichalcogenides can be employed for device channels.

A source/drain region of the first transistor device can have its position shifted with respect to a source/drain region of the second transistor device. For example, the source/drain region of the first transistor device (top) can be offset relative to the source/drain region of the second transistor (bottom) device. The source/drain region of the first transistor device and the source/drain region of the second transistor device can include a metallic source/drain region.

Methods in accordance with embodiments of the present invention can include forming a bottom device and an MDI bonding layer thereover. A placeholder deposition is performed through the MDI to contact a source/drain region of the bottom device. A top device is formed by processing a nanosheet stack (e.g., alternating layers of SiGe/Si) by wafer bonding to the MDI bonding layer. Inner and outer spacers are formed for the top device. “Small” epitaxial growth is performed over exposed portions of channel layers of the nanosheet stack for the top device. A dielectric fill (e.g., an oxide) is performed over the MDI and the source/drain connection placeholder. A replacement metal gate (RMG) process is performed to form gate structures. A source/drain cavity is formed in the dielectric fill, and the placeholder is removed. A metal deposition is performed to form a metallic top source/drain region and a connection to a source/drain region of the bottom device. A contact connecting to the source/drain region of the top device can be formed. Frontside back end of the line (BEOL) metal structures can be formed followed by backside power structure formation.

The metallic source/drain region of the top device not only functions as a source/drain region but also as a signal line. In this way, access to the source/drain region of the bottom device can be provided through the metallic source/drain region to alleviate resistance bottlenecks that can occur at scaled cell height dimensions (e.g., cell heights of ˜60-65 nm or less). Resistance penalty performance benefit of greater than, e.g., 3-4% can be achieved over tapered contact connections.

While illustrative embodiments will be described in terms of nanosheet devices or layers stack devices, embodiments of the present invention can be applied to other stacked device types including but not limited to fin devices, forksheet devices, etc.

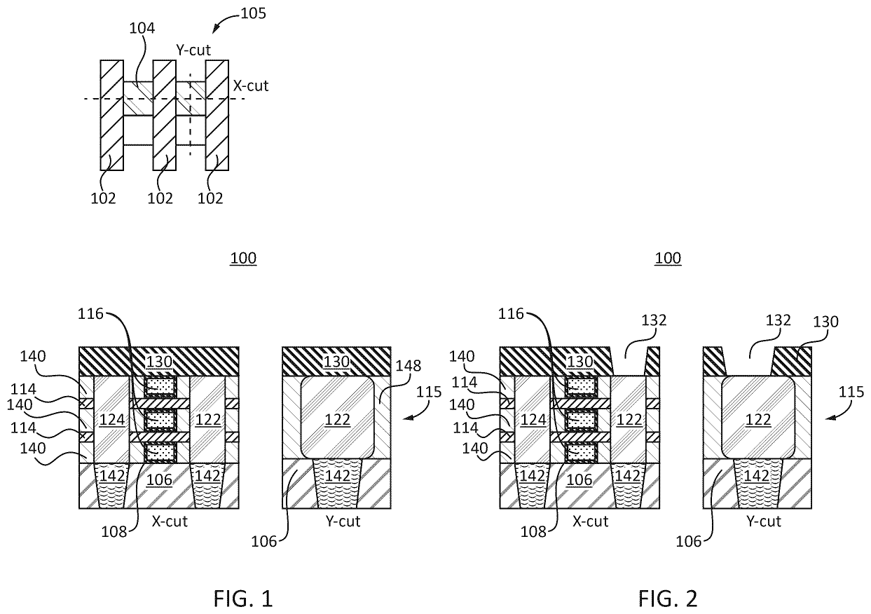

Referring now to the drawings in which like numerals represent the same or similar elements and initially to FIG. 1, devices and methods for manufacturing a stacked field effect transistor (FET) device are shown in accordance with embodiments of the present invention.

A wafer 100 includes a substrate 106 on which the stacked FET device will be fabricated. FIG. 1 depicts two orthogonal views X-cut and Y-cut taken at corresponding sections X-cut and Y-cut in inset 105. Inset 105 shows gate lines 102 and active region line 104 for reference. Corresponding X-cut and Y-cut views are depicted throughout the FIGS. Active region line 104 represents source/drain (S/D) regions for transistor devices, and gate lines 102 represent gate structures for such transistor devices. Transistor channels are formed along the active region line 104 below the gate lines 102.

The substrate 106 can have a single layer or multiple layers on which a stacked FET device will be fabricated. The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

Shallow trench isolation (STI) or STI regions (not shown) can be formed in trenches etched in the substrate 106. STI regions can be formed by depositing dielectric material, such as, e.g., SiO₂, SiOₓN_{y}, SiCO or other suitable compounds. STI regions can be deposited using chemical vapor deposition (CVD), although other deposition methods can be employed. The STI regions can then be etched, e.g., by a reactive ion etch (RIE), to a level of the substrate 106. A layer stack or nanosheet (NS) can be applied to the substrate 106 to provide channels 114 for a first level 115 of field effect transistors (FETs) from alternating layers of semiconductor materials. The other layers (semiconductor layers) are employed to form inner spacers 140. The inner spacers 140 can be formed by filling recesses where nanosheet layers were removed (by etching) with a dielectric material, e.g., SiBCN, SiCN or other suitable dielectric materials.

Source/drain regions 122 and 124 can be grown using an epitaxial growth process using the channels 114 and/or sacrificial placeholders 142 to initiate crystal growth. Source/drain regions 122, 124 are formed on the sacrificial placeholders 142. The substrate 106 is recessed to form trenches, e.g., by reactive ion etching (RIE) in accordance with a pattern formed by the nanosheet. Within the trenches recessed into the substrate 106, the sacrificial placeholders 142 are formed. The sacrificial placeholder 142 can be epitaxially grown in the trenches of the substrate 106. The sacrificial placeholder 142 can include SiGe or other epitaxial grown material that can be selectively removed relative to the substrate 106.

The source/drain regions 122 and 124 are formed in the first level 115. The source/drain regions 122 and 124 can include Si or SiGe. In an embodiment, the source/drain regions 122, 124 can be designated as P-type or N-type devices. For example, if the source/drain regions 122 or 124 include N-type devices then the source/drain regions 122 or 124 can include Si. In another example, if the source/drain regions 122 or 124 include P-type devices then the source/drain regions 122 or 124 can include SiGe. The source/drain regions 122 or 124 can be appropriately doped during their formation. For example, the source/drain regions 122 or 124 can be doped by introducing p dopants (e.g., B, Ga, etc.) during epitaxial formation. Similarly, the source/drain regions 122 or 124 can be doped by introducing n dopants (e.g., P, As, etc.) during epitaxial formation.

In some embodiments, a dummy gate material is first employed for dummy gates (not shown). The dummy gates are removed and a gate dielectric layer 108 is deposited to cover the channels 114 and inner spacers 140. The gate dielectric layer 108 can be formed by, e.g., chemical wet processes, chemical vapor deposition (CVD) and/or atomic layer deposition (ALD). Suitable examples of the gate dielectric layer 108 can include a silicon oxide interface layer followed by a high-K dielectric oxide that can include, but is not limited to: Al₂O₃, ZrO₂, HfO₂, Ta₂O₃, TiO₂ and combinations thereof.

A bottom gate 116 fills spaces between the channels 114 that the dummy gates once occupied. This process is known as a replacement metal gate (RMG) process to form High-K Metal Gate (HKMG) structures for selectively activating FETs. The bottom gate 116 can include at least one gate conductor. The gate conductor can include any conductive metal including, but not limited to W, Ni, Ti, Mo, Ta, Cu, Pt, Ag, Au, Ru, Ir, Rh, and Re, and alloys that include at least one of these conductive materials. The gate conductor can include one or more layers of conductive materials. In one example, a second conductive material may be formed. When a combination of conductive elements is employed, an optional diffusion barrier material such as TaN or WN may be formed between the conductive materials. The gate conductor can be deposited by CVD, plasma enhanced CVD (PECVD), ALD or other suitable deposition process.

An interlayer dielectric (ILD) 148 is deposited over the wafer 100. The ILD 148 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C: H). The ILD 148 can be deposited using CVD, although other deposition methods can be employed. The ILD 148 is planarized, e.g., by chemical mechanical polishing (CMP).

A dielectric layer 130 is deposited over the wafer 100. The dielectric layer 130 can include an oxide, although other dielectric materials can be employed. The dielectric layer 130 can be deposited using CVD, ALD or any other suitable deposition methods. The dielectric layer 130 can include a bonding dielectric to which another nanosheet can be applied to process a second level 215 of FETs. The dielectric layer 130 provides a barrier between the bottom gate 116 and a gate to be formed. The dielectric layer 130 provides separation between the FETs in the first level 115 to enable continued processing for the formation of upper layers of FETs. The dielectric layer 130 can be referred to as middle dielectric isolation (MDI).

Referring to FIG. 2, a lithographic patterning process is performed to create an etch mask employed to locate and etch a through opening 132 through the dielectric layer 130. The through opening 132 exposes the source/drain region 122. The through opening 132 can be etched using, e.g., RIE.

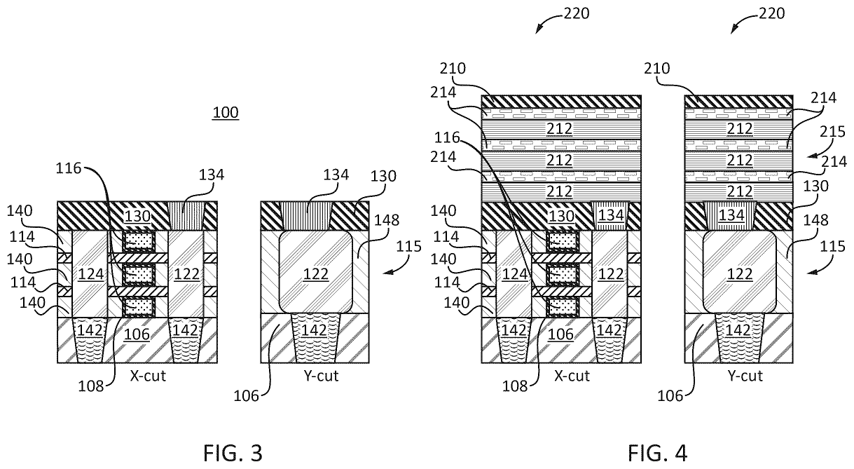

Referring to FIG. 3, the through opening 132 is filled with a dielectric material and a surface of the dielectric layer 130 is planarized to form a placeholder 134. The dielectric material of the placeholder 134 can include, e.g., SiO₂, SiO SiOC, SiOCN, SiON or any other suitable material. The dielectric material for the placeholder 134 can be deposited using a CVD or other deposition method. The planarization process can include a chemical mechanical polish (CMP).

Referring to FIG. 4, a layer stack 220 or stacks are applied (e.g., bonded) to or formed on the first level 115. In an embodiment, one or more nanosheets (NS) are applied to the first level 115. In an embodiment, the layer stack 220 of the nanosheet includes channels 214 for the second level 215 of field effect transistors (FETs) in alternating layers of the nanosheet. The other alternating layers 212 can include a different material than the channels 214. For example, if the channels 214 include Si, the alternating layers 212 can include SiGe.

A dielectric layer 210 is formed on the layer stack 220. The dielectric layer can include, e.g., an oxide.

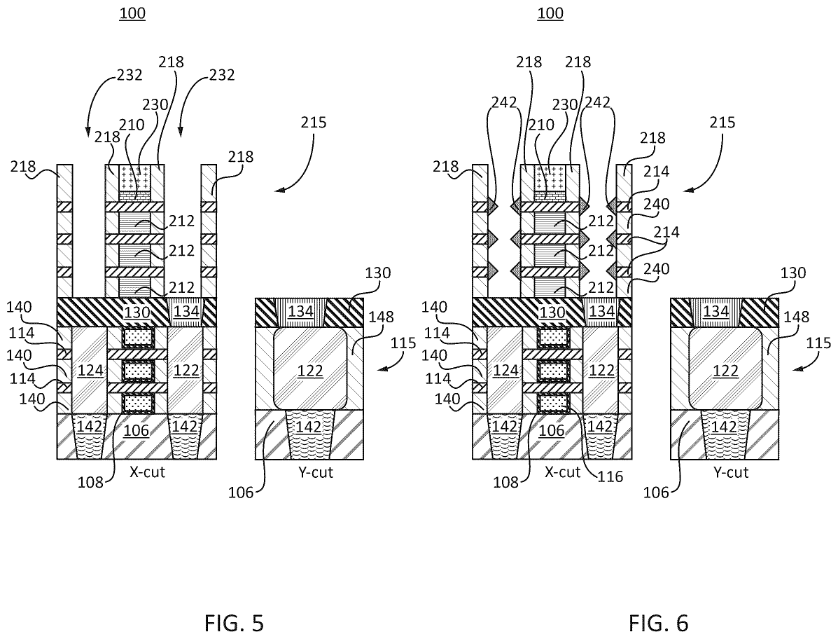

Referring to FIG. 5, the layer stack 220 of the nanosheet is patterned by forming a hard mask 230 (e.g., amorphous Si) on the dielectric layer 210 and forming dielectric sidewall spacers 218 to provide an etch mask for etching the layer stack 220 to open up canyons or trenches 232. The trenches 232 expose the dielectric layer 130 and the placeholder 134. The alternating layers 212 are recessed and filled with a dielectric material to form inner spacers 240. The inner spacers 240 can be formed by filling recesses where nanosheet layers were removed (by etching) with a dielectric material, e.g., SiBCN, SiCN or other suitable dielectric materials.

Referring to FIG. 6, channel caps 242 can be grown with an epitaxial growth process using the channels 214 to initiate crystal growth. The channel caps 242 can include an epitaxially grown Si; however, other semiconductor materials can be employed. The channel caps 242 can include conical or triangularly shaped cross-section structures. In other embodiments, the channel caps 242 can include semicircular cross-sections, rounded triangular cross-sections or any other shape that increases interfacial surface area with a fill material to be employed in later steps. The channel caps 242 can be merged with neighboring channel caps 242 or remain unmerged and separate from neighboring channel caps 242.

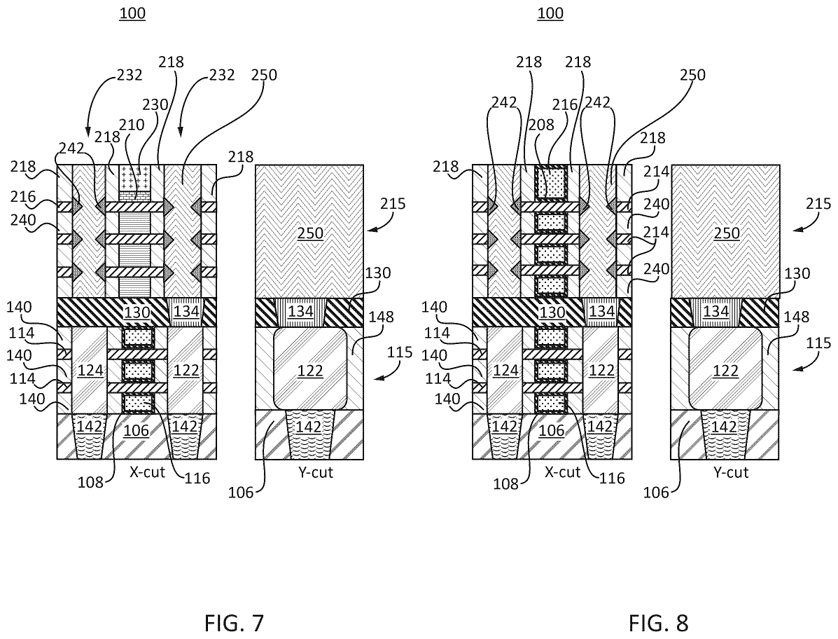

Referring to FIG. 7, a dielectric fill material 250 is deposited over the wafer 100 to fill in spaces and act as a block mask to protect structures during further processing. In an embodiment, the dielectric fill material 250 can include a flowable dielectric material, such as a flowable oxide. The flowable material can be deposited using a CVD process.

Referring to FIG. 8, material for the alternating layers 212 is removed by an etch process. A gate dielectric layer 208 is deposited to cover the channels 114, inner spacers 240 and the spacers 218. The gate dielectric layer 208 can be formed by, e.g., chemical wet processes, CVD and/or ALD. Suitable examples of the gate dielectric layer 208 can include a silicon oxide interface layer followed by a high-K dielectric oxide that can include, but is not limited to: Al₂O₃, ZrO₂, HfO₂, Ta₂O₃, TiO₂ and combinations thereof.

A top gate 216 fills spaces between the channels 114 to form HKMG structures for selectively activating FETs. The top gate 216 can include at least one gate conductor. The gate conductor can include any conductive metal including, but not limited to W, Ni, Ti, Mo, Ta, Cu, Pt, Ag, Au, Ru, Ir, Rh, and Re, and alloys that include at least one of these conductive materials. The gate conductor can include one or more layers of conductive materials. In one example, a second conductive material may be formed. When a combination of conductive elements is employed, an optional diffusion barrier material such as TaN or WN may be formed between the conductive materials. The gate conductor can be deposited by CVD, PECVD, ALD or other suitable deposition process.

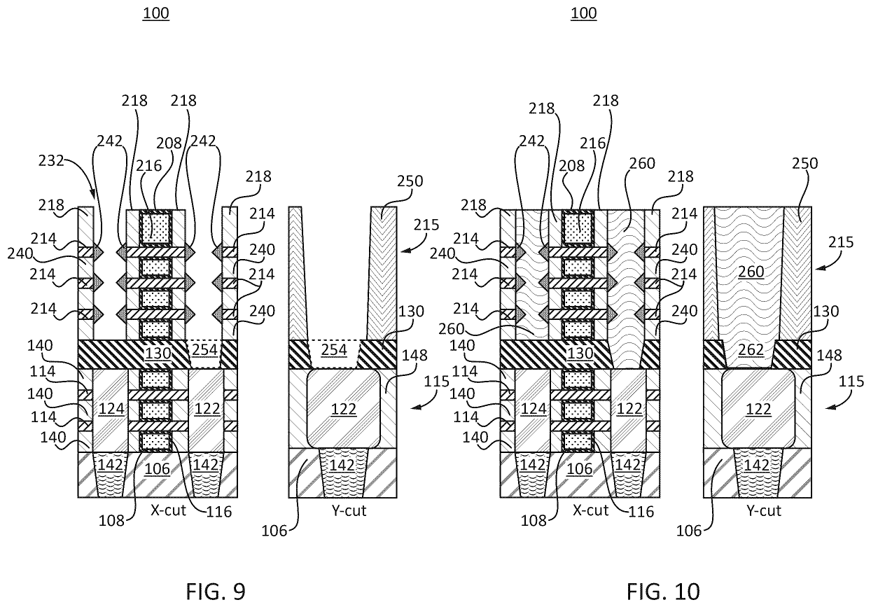

Referring to FIG. 9, an etch mask (not shown) is formed to provide an etch pattern to remove the dielectric fill material 250 from trenches 232 and to form an opening 252. The opening 252 is etched down to the placeholder 134. The placeholder 134 is also removed selective to the inner spacers 240, the dielectric layer 130 and the underlying source/drain region 122. Opening 254 is formed by the removal of the placeholder 134. The opening 254 exposes the source/drain region 122 so that a connection can be formed thereto in later steps.

Referring to FIG. 10, a conductive fill is performed to make a connection with the source/drain region 122 from a top or frontside of the wafer 100. Prior to the conductive fill, a silicide liner (not shown), such as Ti, Ni, NiPt can be deposited first, then a diffusion barrier (not shown) can be formed. The diffusion barrier can include, e.g., TiN, TaN, or similar materials. The silicide liner and the diffusion barrier can be deposited (e.g., by ALD) to cover the channel caps 242 and source/drain region 122 (if a semiconductor material is employed for the source/drain region 122).

A conductive fill is performed to fill the opening 254. The conductive fill can include materials, such as, e.g., W, Co, and alloys or combinations of these and other conductive materials. In a particularly useful embodiment, the conductive fill includes W. Other suitable metals are also contemplated for metallic source/drain regions, as described herein. These suitable materials provide dual functionality and act as both a source/drain region as well as a conductive line or contact. The conductive fill can be formed using a deposition method, such as, e.g., CVD, PECVD, ALD or any other suitable deposition method. The conductive fill is planarized, e.g., by CMP, to form metallic source/drain regions 260 and a metallic via or through contact 262.

The metallic source/drain regions 260 contacts the channel caps 242 to make low resistance transitions between the metal of the metallic source/drain regions 260 and the channels 214. The through contact 262 traverses the dielectric layer 130 (MDI) to make a low resistance connection between the metallic source/drain region 260 and the source/drain regions 122.

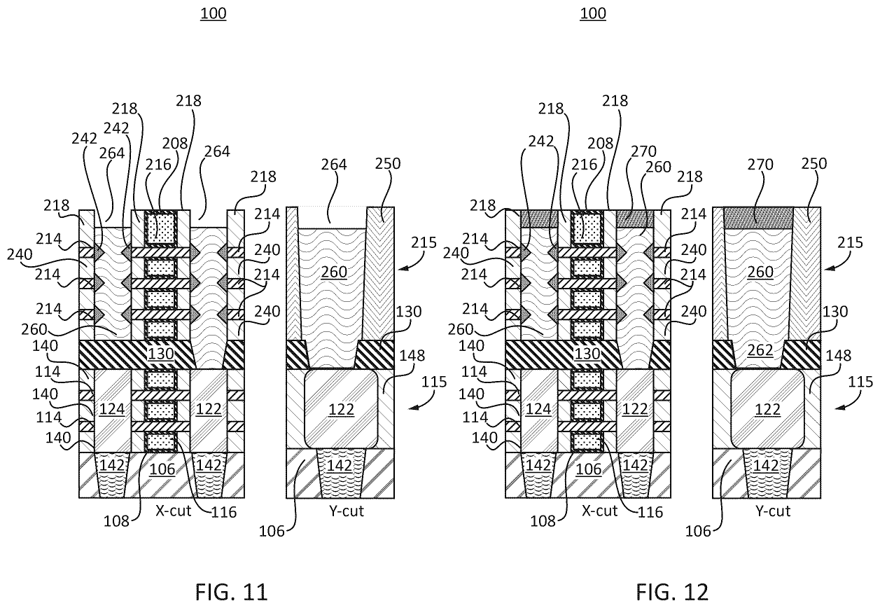

Referring to FIG. 11, a metal recess is performed to recess the metallic source/drain regions 260 to form recesses 264. The metal recess includes a selective etch process that removes the material of the metallic source/drain regions 260 without removing the material of the gate dielectric layer 208, spacers 218 and the dielectric fill material 250.

Referring to FIG. 12, the recesses 264 are refilled using a dielectric material 270. The dielectric material 270 is compatible with the dielectric fill material 250 and can include a same or similar material to the dielectric fill material 250. A planarization process may be performed (e.g., CMP) to level off a top surface of the wafer 100.

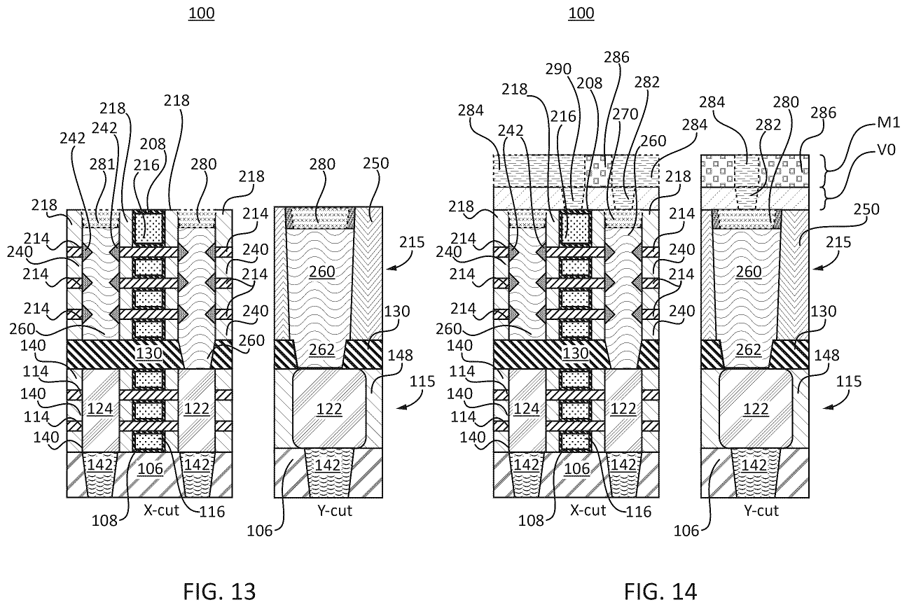

Referring to FIG. 13, contact openings are patterned into the dielectric material 270 using a lithographic pattern and etch. A conductive fill is performed to fill the contact openings. The conductive fill can include materials, such as, e.g., Cu, Ru, Mo, Rh, W, Ir, and alloys or combinations of these and other conductive materials. In a particularly useful embodiment, the conductive fill includes W. The conductive fill can be formed using a deposition method, such as, e.g., CVD, PECVD, ALD or any other suitable deposition method. The conductive fill is planarized, e.g., by CMP, to form contacts 280 and 281.

Referring to FIG. 14, metallization structures for a frontside back end of the line (BEOL) layer are formed to connect to gates and source/drain regions of the field effect transistors. In an embodiment, a dielectric layer 288 is formed over the contacts 280 and 281 and patterned to open via holes. The dielectric layer 288 can include an oxide, a nitride, an oxynitride or any suitable dielectric material. Vias 282 and 290 are formed in the via holes (e.g., at V0 level). A diffusion barrier can be formed in the via openings. The diffusion barrier can include, e.g., TiN, TaN, or similar materials. A conductive fill is performed to fill the contact openings. The conductive fill can include materials, such as, e.g., Cu, Ru, Mo, Rh, W, Ir, and alloys or combinations of these and other conductive materials. In a particularly useful embodiment, the conductive fill includes Ru. The conductive fill can be formed using a deposition method, such as, e.g., CVD, PECVD, ALD or any other suitable deposition method. The conductive fill is planarized, e.g., by CMP, to form vias 282 and 290.

The via 282 provides a gate contact that connects to the gate 216 for a top FET, and the via 282 connects to the metallic source/drain region 260 through the contact 280 for the top FET. Another dielectric layer 286 is formed over the vias 282 and 290. The dielectric layer 286 can include an oxide, a nitride, an oxynitride or any suitable dielectric material. The dielectric layer 286 is patterned to open up trenches for forming metal lines 284 (e.g., at M1 level). The metal lines 284 are formed in the trenches. A diffusion barrier can be formed in the trenches. The diffusion barrier can include, e.g., TiN, TaN, or similar materials. A conductive fill is performed to fill the trenches. The conductive fill can include materials, such as, e.g., Cu, Ru, Mo, Rh, W, Ir, and alloys or combinations of these and other conductive materials. In a particularly useful embodiment, the conductive fill includes Ru. The conductive fill can be formed using a deposition method, such as, e.g., CVD, PECVD, ALD or any other suitable deposition method. The conductive fill is planarized, e.g., by CMP, to form the metal lines 284. Processing can continue with additional levels of vias and metal lines as needed to complete the frontside BEOL layer.

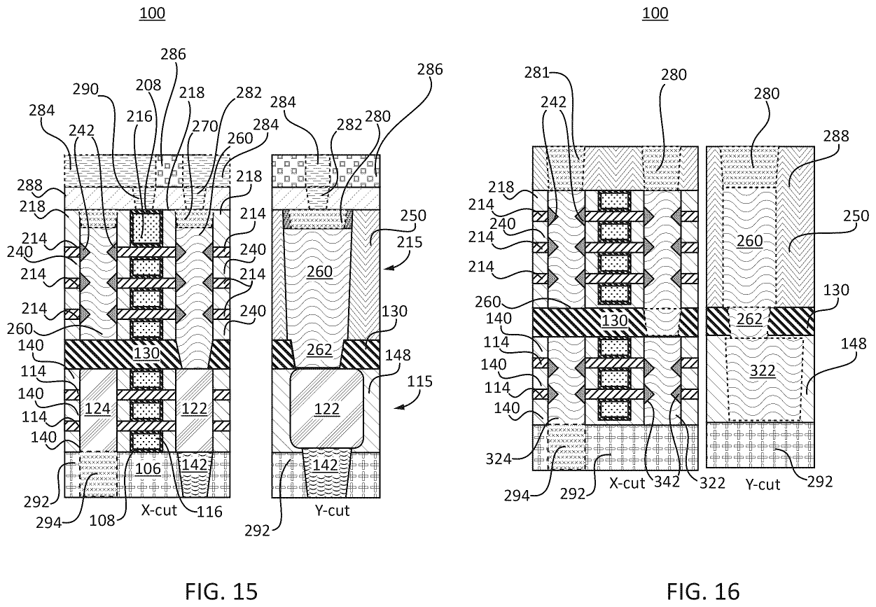

Referring to FIG. 15, a carrier wafer (not shown) can be bonded to the wafer 100 on the frontside BEOL layer. The carrier wafer provides support and transportability to the wafer 100 for further processing which includes flipping the wafer 100 and removing portions of a bottom side. The wafer 100 can be flipped to process features on the bottom side. However, for clarity and consistency, the wafer 100 will be shown in the FIGS. in a same orientation as previously described with continued and consistent reference to bottom/top. The substrate 106 is removed from the bottom side of the wafer 100. The substrate 106 can be removed by an etch process that is selective to the sacrificial placeholders 142.

An interlayer dielectric (ILD) 292 is formed to replace the substrate 106 that was removed. The ILD 292 can be formed in accordance with the same of different processes and ILD 148 and can include a same or different material. In one embodiment, the ILD 292 includes a nitride. The ILD 292 can be planarized, e.g., by CMP, to expose the sacrificial placeholders 142.

Some of the sacrificial placeholders 142 exposed from the bottom side are removed by etching. The sacrificial placeholders 142 designated for contact formation are not masked so that the sacrificial placeholders 142 are removed to expose the source/drain region 124. The etch process can include a dry etch or wet etch that selectively removes the sacrificial placeholders 142 to form contact openings.

In some embodiments, a silicide liner (not shown), such as Ti, Ni, NiPt is deposited first, then a diffusion barrier (not shown) can be formed in the openings left by removing the sacrificial placeholders 142 prior to a conductive fill. The diffusion barrier can include, e.g., TiN, TaN, or similar materials. A conductive fill is performed to fill the openings. The conductive fill can include materials, such as, e.g., Cu, Ru, Mo, Rh, W, Ir, and alloys or combinations of these and other conductive materials. In a particularly useful embodiment, the conductive fill includes W. The conductive fill can be formed using a deposition method, such as, e.g., CVD, PECVD, ALD or any other suitable deposition method. The conductive fill is planarized, e.g., by CMP, to form backside contacts 294.

Processing continues with the formation of a backside interconnect layer (not shown), which can include metal structures and dielectric layers to complete the bottom side of a stacked FET device and provide electrical access and power to devices formed therein. The backside interconnect layer is formed on the ILD 292 and connects to the backside contacts 294 of the wafer 100.

Referring to FIG. 16, in another embodiment, metallic source/drain regions 322 and 324 can be employed. The metallic source/drain regions 322 and 324 can replace the epitaxially grown source/drain regions 122, 124. The processing can include epitaxially growing channels caps 342 on channels 114. Instead of epitaxially growing source/drain regions, the metallic source/drain regions 322 can be deposited over the channel caps 342. A silicide liner can be placed over the channel caps 342 prior to a conductive fill. The conductive fill can include materials, such as, e.g., W, Co or any suitable metal, metal alloys or combinations of these and other conductive materials. The conductive fill can be formed using a deposition method, such as, e.g., CVD, PECVD, ALD or any other suitable deposition method. The conductive fill is planarized, e.g., by CMP, to form the metallic source/drain regions 322 and 324. Processing can continue as described.

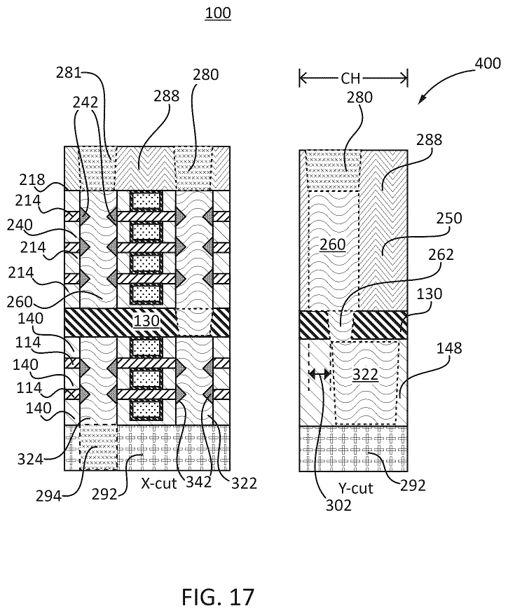

Referring to FIG. 17, in another embodiment, source/drain regions can be shifted relative to one another. If the Y-cut of FIG. 17 depicts a cell height (CH) of a cell 400, the metallic source drain region 260 of the top FET is shifted to one side of the cell 400 while the metallic source/drain region 322 of the bottom FET is shifted to an opposite side of the cell 400. It should be understood that the metallic source drain region 260 of the top FET can be shifted to the opposite side of the cell 400 and the metallic source/drain region 322 of the bottom FET can be shifted to the one side of the cell 400. It should also be understood that the metallic source/drain region 322 can include a semiconductor source/drain region (e.g., source/drain region 122). Processing can continue as described.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor-or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a first field effect transistor stacked on a second field effect transistor, the first field effect transistor having a metallic source/drain region;
a second source/drain region of the second field effect transistor separated from the metallic source/drain region by a middle dielectric isolation layer; and
a through contact passing through the middle dielectric isolation layer to connect the metallic source/drain region to the second source/drain region.

2. The semiconductor device as recited in claim 1, wherein the metallic source/drain region includes W or an alloy thereof.

3. The semiconductor device as recited in claim 1, wherein the metallic source/drain region includes Co or an alloy thereof.

4. The semiconductor device as recited in claim 1, wherein the metallic source/drain region connects to device channels by channel caps.

5. The semiconductor device as recited in claim 1, wherein the second source/drain region includes a metal.

6. The semiconductor device as recited in claim 1, wherein the metallic source/drain region is laterally offset from the second source/drain region.

7. The semiconductor device as recited in claim 1, further comprising a contact to connect the metallic source/drain region to a back end of the line layer on a frontside of the semiconductor device.

8. The semiconductor device as recited in claim 7, further comprising a contact connected to the second field effect transistor from a backside of the semiconductor device.

9. A semiconductor device, comprising:
a first field effect transistor stacked on a second field effect transistor, the first field effect transistor having a first metallic source/drain region;
a second metallic source/drain region of the second field effect transistor separated from the first metallic source/drain region by a middle dielectric isolation layer; and
a through contact passing through the middle dielectric isolation layer to connect the first metallic source/drain region to the second metallic source/drain region.

10. The semiconductor device as recited in claim 9, wherein the first metallic source/drain region includes W or alloy thereof.

11. The semiconductor device as recited in claim 9, wherein the first metallic source/drain region includes Co or alloy thereof.

12. The semiconductor device as recited in claim 9, wherein the second metallic source/drain region includes W or alloy thereof.

13. The semiconductor device as recited in claim 9, wherein the second metallic source/drain region includes Co or alloy thereof.

14. The semiconductor device as recited in claim 9, wherein the first metallic source/drain region connects to device channels by channel caps.

15. The semiconductor device as recited in claim 9, wherein the second metallic source/drain region connects to device channels by channel caps.

16. The semiconductor device as recited in claim 9, wherein the first metallic source/drain region is laterally offset from the second metallic source/drain region.

17. The semiconductor device as recited in claim 9, further comprising a contact connected to the second field effect transistor from a backside of the semiconductor device.

18. A semiconductor device, comprising:
a first field effect transistor stacked on a second field effect transistor, the first field effect transistor having a first metallic source/drain region, the first metallic source/drain region connecting to device channels of the first field effect transistor by channel caps;
a second metallic source/drain region of the second field effect transistor separated from the first metallic source/drain region by a middle dielectric isolation layer, the second metallic source/drain region connecting to device channels of the second field effect transistor by channel caps; and
a through contact passing through the middle dielectric isolation layer to connect the first metallic source/drain region to the second metallic source/drain region.

19. The semiconductor device as recited in claim 18, wherein the first metallic source/drain region is laterally offset from the second metallic source/drain region.

20. The semiconductor device as recited in claim 18, further comprising a contact to connect the first metallic source/drain region to a back end of the line layer on a frontside of the semiconductor device.

21. The semiconductor device as recited in claim 20, further comprising a contact connected to the second field effect transistor from a backside of the semiconductor device.

22. A semiconductor device, comprising:
a first field effect transistor stacked on a second field effect transistor, the first field effect transistor having a first metallic source/drain region, the first metallic source/drain region connecting to device channels of the first field effect transistor by channel caps;
a second metallic source/drain region of the second field effect transistor separated from the first metallic source/drain region by a middle dielectric isolation layer, the second metallic source/drain region connecting to device channels of the second field effect transistor by channel caps;
a through contact passing through the middle dielectric isolation layer to connect the first metallic source/drain region to the second metallic source/drain region;
a frontside contact to connect the first metallic source/drain region to a back end of the line layer; and
a backside contact connected to the second field effect transistor from a backside of the semiconductor device.

23. The semiconductor device as recited in claim 22, wherein the first metallic source/drain region is laterally offset from the second metallic source/drain region.

24. A method for forming a semiconductor device, comprising:
forming a bottom field effect transistor;
depositing a middle dielectric isolation layer over the bottom field effect transistor;
forming an opening in the middle dielectric isolation layer over a source/drain region of the bottom field effect transistor;
forming a placeholder in the opening of the middle dielectric isolation layer;
forming channels and gate structures of a top field effect transistor;
performing a dielectric fill;
opening the dielectric fill over the placeholder;
removing the placeholder; and
depositing a metal through the middle dielectric isolation layer to form a through contact to the source/drain region of the bottom field effect transistor and to form a metallic source/drain region for the top field effect transistor.

25. The method as recited in claim 24, further comprising forming channel caps wherein the metallic source/drain region connects to the channels by the channel caps.
